(19) United States
(12) Patent Application Publication
(10) Pub. No.: US 2014/0091453 A1
(43) Pub. Date: Apr. 3, 2014

(54) COOLING DEVICE AND SEMICONDUCTOR DEVICE

(71) Applicant: KABUSHIKI KAISHA TOYOTA JIDOSHOKKI, Kariya-shi (JP)

(72) Inventors: Shogo MORI, Kariya-shi (JP); Yuri OTOBE, Kariya-shi (JP); Naoki KATO, Kariya-shi (JP); Shinsuke NISHI, Kariya-shi (JP); Tomoya HIRANO, Oyama-shi (JP); Seiji MATSUSHIMA, Oyama-shi (JP)

(73) Assignee: KABUSHIKI KAISHA TOYOTA JIDOSHOKKI, Kariya-shi (JP)

(21) Appl. No.: 14/040,019

(22) Filed: Sep. 27, 2013

(30) Foreign Application Priority Data
Oct. 2, 2012 (JP) 2012-220500

(51) Int. Cl. F28F 3/02; H01L 23/367

(52) U.S. Cl. CPC F28F 3/02; H01L 23/3677
USPC 257/712; 165/104.33

(57) ABSTRACT

A cooling device includes a base and a plurality of radiator fins. The base includes an exterior, an interior, an inlet, and an outlet. A heat generation element is connected to the exterior of the base. The radiator fins are located near the heat generation element in the interior of the base. The radiator fins are arranged from the inlet to the outlet. Each radiator fin has a sidewise cross-section with a dimension in a flow direction of the cooling medium and a dimension in a lateral direction orthogonal to the flow direction of the cooling medium. The dimension in the flow direction is longer than the dimension in the lateral direction. The radiator fins are separated from one another by a predetermined distance in the lateral direction.

### BACKGROUND OF THE INVENTION

The present invention relates to a cooling device that cools a heat generation element connected to a base of the cooling device with a cooling medium that flows through the base, and to a semiconductor device including a cooling device connected with an insulation substrate, on which a semiconductor element is mounted.

A cooling device known in the prior art that cools heat generation elements, such as electronic components, includes a base and a flow passage formed in the base. The heat generation elements are mounted on an exterior of the base. A cooling medium flows through the flow passage (refer to, for example, Japanese Laid-Open Patent Publication No. 2012-29539).

In the cooling device disclosed in the above publication, plurality of pin-shaped radiator fins are arranged in the flow passage. The radiator fins and a wall surface of the flow passage form an inner surface of the base. The radiator fins increase the area of the inner surface of the base that comes into contact with the cooling medium. When the heat generated by the heat generation elements is transferred to the base, the radiator fins increase the amount of heat exchanged between the inner surface of the base and the cooling medium in the base. This improves the efficiency for cooling the heat generation elements.

In the above cooling device, to further improve the cooling efficiency for the heat generation elements, the diameter of the radiator fins, which have a circular cross-section, may be increased to enlarge the surface area of each radiator fin.

However, this would increase the width of each radiator fin. That is, the dimension of the radiator fin would be increased in a lateral direction orthogonal to the flow direction of the cooling medium. As a result, the radiator fin increases flow resistance in the flow passage, which in turn increases pressure loss when the cooling medium passes through the flow passage.

### SUMMARY OF THE INVENTION

The object of the present invention is to provide a cooling device and a semiconductor device that suppress an increase in pressure loss when a cooling medium passes through an interior of a base and that improve the efficiency for cooling heat generation elements.

To achieve the above object, one aspect of the present invention is a cooling device including a base and a plurality of pin-shaped radiator fins. The base includes an exterior, an interior, an inlet, and an outlet. A heat generation element is connected to the exterior. The radiator fins are located in the interior of the base at a portion near the heat generation element. The radiator fins are arranged from the inlet to the outlet. The cooling device cools the heat generation element with a cooling medium flowing in the interior of the base from the inlet to the outlet. Each of the radiator fins includes a sidewise cross-section having a dimension in a flow direction of the cooling medium and a dimension in a lateral direction orthogonal to the flow direction of the cooling medium, and the dimension in the flow direction is longer than the dimension in the lateral direction. The radiator fins are separated from one another by a predetermined distance in the lateral direction.

Other aspects and advantages of the invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is an exploded perspective view of a cooling device according to the first embodiment of the present invention;

FIG. 2 is a cross-sectional view of the cooling device in FIG. 1;

FIG. 3 is a schematic diagram showing operation of the cooling device in FIG. 1;

FIGS. 4A to 4D are enlarged cross-sectional views respectively showing main parts of cooling devices according to other embodiments.

### DETAILED DESCRIPTION OF THE PREFERRED EMBODIMENTS

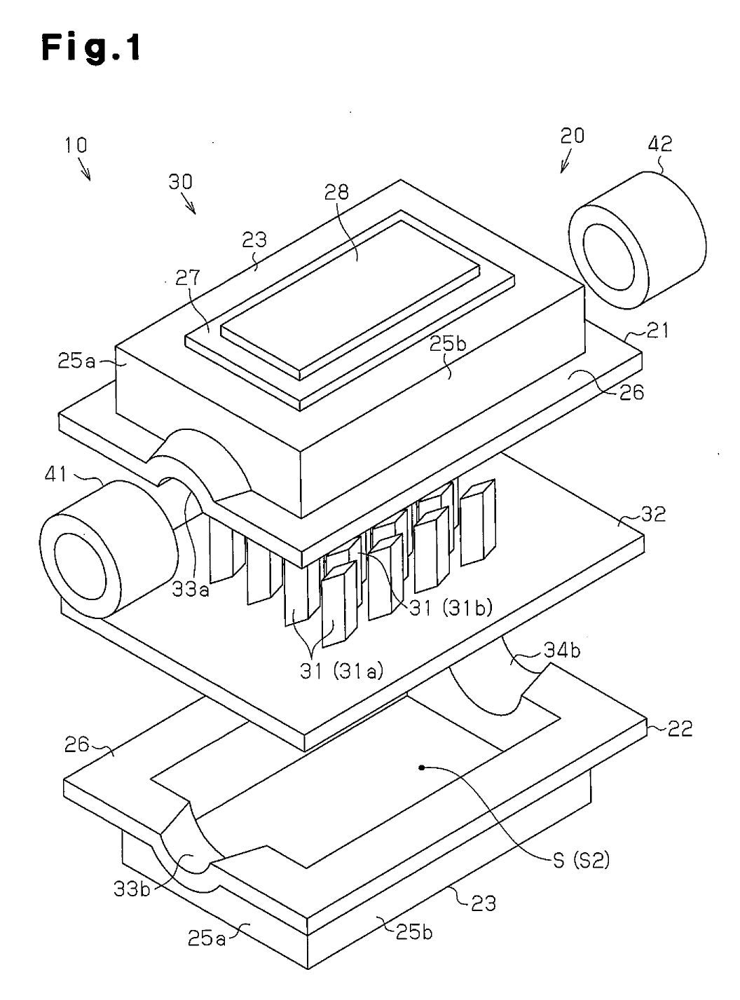

One embodiment of the present invention will now be described with reference to FIGS. 1-3.

Referring to FIG. 1, in the present embodiment, a cooling device 10 includes a base 20. The base 20 includes an aluminum first base forming member 21 and an aluminum second base forming member 22. The first and second base forming members 21 and 22 have the same shape, and are coupled to one another. Each of the first and second base forming members 21 and 22 includes a bottom plate 23, side walls 25a, side walls 25b, and a plate-like joint 26. The bottom plate 23 is rectangular as viewed from above. The side walls 25a are arranged on the short sides of the bottom plate 23. The side walls 25b are arranged on the long sides of the bottom plate 23. The joint 26 extends outward from each distal end of the side walls 25a and 25b in a substantially horizontal direction.

The base 20 includes an interior region S. The interior region S serves as a flow passage through which a cooling medium flows. In the first base forming member 21, the bottom plate 23 includes an inner surface, which faces the interior region S, and an outer surface, which is an opposite side of the inner surface. A semiconductor element 28, which serves as a heat generation element is connected to the outer surface by a rectangular plate-like insulation substrate 27. The insulation substrate 27 includes a lower surface connected to the first base forming member 21 by a metal plate (not shown), which functions as a joint layer. The longitudinal direction of the insulation substrate 27 coincides with the longitudinal direction of the first base forming member 21. The insulation substrate 27 includes an upper surface on which the semiconductor element 28 is mounted. A metal plate (not shown), which functions as a wiring layer is arranged between the upper surface and the semiconductor element 28. In the present embodiment, the insulation substrate 27, on which the semiconductor element 28 is mounted, is coupled to the outer surface of the base 20 of the cooling device 10 to form a semiconductor device 30.

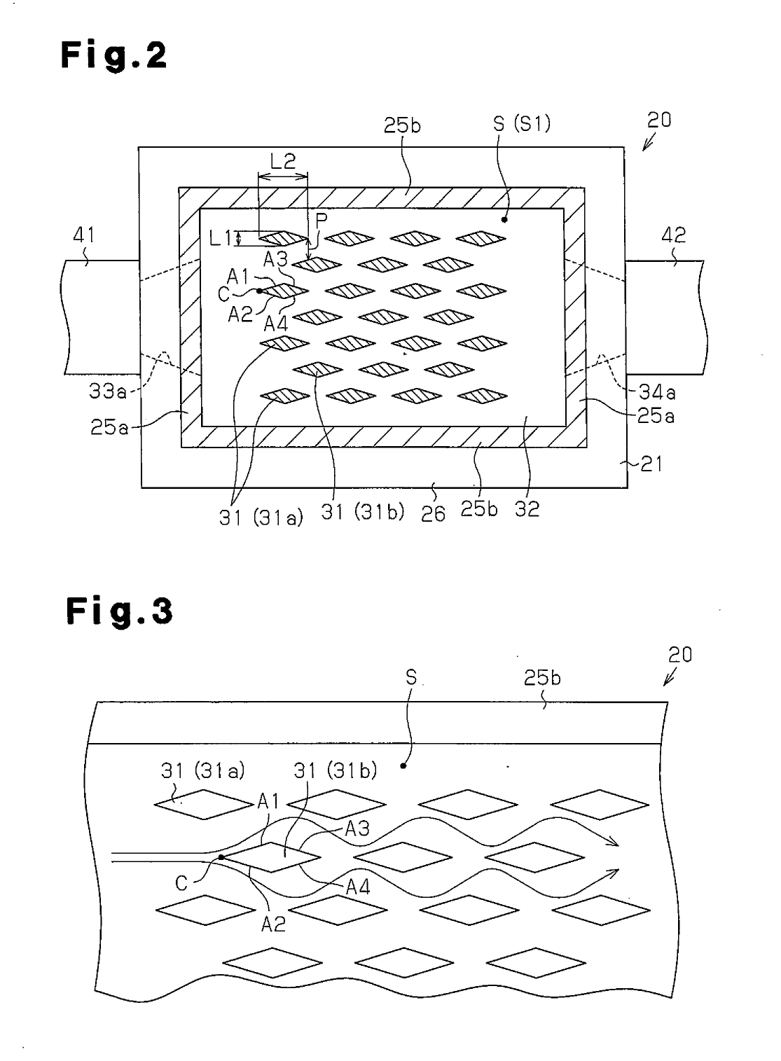

A support plate 32 is arranged between the first and second base forming members 21 and 22. The support plate 32 supports pin-shaped radiator fins 31 that are accommodated in the interior region S of the base 20. The support plate 32 is a rectangular plate and has the same size as the joint 26. The support plate 32 is held between joints 26 so that the support plate 32 faces the bottom plates 23 of the first base forming member 21 and the second base forming member 22. The joint 26 of the first base forming member 21, the joint 26 of the second base forming member 22, and the support plate 32 are brazed and coupled together. The brazing hermetically seals the interface between the joints 26 and the support plate 32. The support plate 32 divides the interior region S into a first flow passage S1 (refer to FIG. 2) and a second flow passage S2.

In the first base forming member 21, the two longitudinal ends of the joint 26 include recesses 33a and 34a as shown in FIG. 2. Similarly, in the second base forming member 22, the longitudinal ends of the joint 26 include recesses 33b and 34b. The joints 26 of the first base forming member 21 and the second base forming member 22 are joined with the support plate 32. As a result, the recesses 33a and 34a of the first base forming member 21 form a communication portion that communicates the first flow passage S1 with the outside of the base 20. Similarly, the recesses 33b and 34b of the second base forming member 22 form a communication portion that communicates the second flow passage S2 with the outside of the base 20.

The rims of the recesses 33a and 33b of the base forming members 21 and 22 are used to couple a cylindrical inflow pipe 41. The inflow pipe 41 draws cooling medium into the first flow passage S1 through the recess 33a and into the second flow passage S2 through the recess 33b. Similarly, the rims of the recesses 34a and 34b of the base forming members 21 and 22 are used to couple a cylindrical outflow pipe 42. The outflow pipe 42 discharges the cooling medium out of the first flow passage S1 through the recess 34a and out of the second flow passage S2 through the recess 34b. The cooling medium flows from the recesses 33a and 33b to the recesses 34a and 34b in the longitudinal direction of the base forming members 21 and 22. The recesses 33a and 33b serve as an inlet of the base 20. The recesses 34a and 34b serve as an outlet of the base 20.

Referring to FIG. 2, a plurality of pin-shaped radiator fins 31 are arranged in a staggered manner, as view from above, on upper and lower surfaces of the support plate 32 from the recesses 33a and 33b to the recesses 34a and 34b. More specifically, radiator fins 31 arranged on the upper surface of the support plate 32 are proximate to the heat generation element in the base 20. Radiator fins 31 arranged on the lower surface of the support plate 32 are distant from the heat generation element in the base 20. The radiator fins 31 supported on the upper surface of the support plate 32 and the radiator fins 31 supported on the lower surface of the support plate 32 have the same layout. More specifically, seven lines of radiator fins 31 are arranged on each of the upper and lower surfaces of the support plate 32. The seven lines include four lines of radiator fins 31a and three lines of radiator fins 31b alternately arranged in the longitudinal direction of the support plate 32. Each line of the radiator fins 31a includes four radiator fins 31a arranged at fixed intervals in a lateral direction of the support plate 32. Each line of the radiator fins 31b includes three radiator fins 31b arranged at fixed intervals in the lateral direction of the support plate 32. The radiator fins 31b are arranged between the adjacent radiator fins 31a in the lateral direction. In this case, the radiator fins 31a and the radiator fins 31b are arranged in the flow direction of the cooling medium so that a downstream portion of each first radiator fin 31a overlaps with an upstream portion of a second radiator fin 31b in the lateral direction of the support plate 32, which is orthogonal to the flow direction of the cooling medium. That is, downstream portions of the first radiator fins 31a and upstream portions of the second radiator fins 31b are arranged to overlap one another along lines parallel to the lateral direction of the support plate 32. The radiator fins 31a are separated from the radiator fins 31b by distance P in the lateral direction of the support plate 32.

Each radiator fin 31 protrudes from the support plate 32 with a constant width and has a sidewise cross-section that is uniform throughout the radiator fin 31 in the direction of protrusion. The sidewise cross-section is the cross-section of the radiator fin 31 in a direction intersecting, that is, orthogonal to, the direction in which the radiator fin 31 protrudes. The radiator fin 31 has a rhombic sidewise cross-section in the interior region S so that its dimension L2 in the flow direction of the cooling medium is larger than its dimension L1 in the lateral direction orthogonal to the flow direction of the cooling medium. That is, the sidewise cross-section of the radiator fin 31 has a relatively long diagonal in the flow direction of the cooling medium. The sidewise cross-section of the radiator fin 31 has a relatively short diagonal in the lateral direction. The sidewise cross-section of the radiator fin 31 is outlined by four linear sides A1, A2, A3, and A4. The two sides A1 and A2 are directed from an upstream side to a downstream side in the flow direction of the cooling medium and extended away from each other in the lateral direction. The sides A1 and A2 intersect to form a corner C. The corner C faces the upstream side in the flow direction of the cooling medium.

The distance P between each radiator fin 31a and the adjacent radiator fin 31b is shorter than the dimension L2 of the sidewise cross-section of the radiator fin 31 in the flow direction of the cooling medium. Here, the distance P is the distance between a radiator fin 31a and an adjacent radiator fin 31b in the lateral direction. The two sides A1 and A2 intersect to form an acute angle at the corner C of the radiator fin 31. Each radiator fin 31 is protruded from the support plate 32 by the same amount. Each radiator fin 31 protruding upward from the upper surface of the support plate 32 has a distal end coupled to the bottom plate 23 of the first base forming member 21. Each radiator fin 31 protruding downward from the lower surface of the support plate 32 has a distal end coupled to the bottom plate 23 of the second base forming member 22.

The operation of the above cooling device 10 will be now described.

In the cooling device 10 of the present embodiment, the sidewise cross-section of the radiator fin 31 has the dimension L2 in the flow direction of the cooling medium that is longer than the dimension L1 in the lateral direction. In contrast, a radiator fin known in the prior art has a circular sidewise cross-section, which has a dimension in the flow direction of the cooling medium equal to a dimension in the lateral direction. Therefore, unlike the prior art, the sidewise cross-section of the radiator fin 31 of the present embodiment enlarges the dimension of the radiator fin 31 in the flow direction of the cooling medium without enlarging the dimension in the lateral direction orthogonal to the flow direction of the cooling medium.

In the radiator fin 31 of the present embodiment, as the dimension of the radiator fin 31 increases in the flow direction of the cooling medium, the area of contact between the cooling medium and the radiator fin 31 increases. As a result, the radiator fin 31 exchanges more heat with the cooling medium. Thus, the heat transferred to the base 20 from the semiconductor element 28 is efficiently exchanged between the radiator fin 31 and the cooling medium. Therefore, the cooling device 10 improves the efficiency for cooling the semiconductor element 28.

Further, unlike the prior art, the dimension of the radiator fin 31 is unchanged in the lateral direction orthogonal to the flow direction of the cooling medium in the present embodiment. That is, the radiator fin 31 does not significantly change the degree in which the radiator fin 31 blocks the flow of the cooling medium as compared with the prior art. Therefore, the present embodiment suppresses an increase in the pressure loss caused by the radiator fin 31 when the cooling medium flows through the interior region S of the base 20.

In particular, the corner C of the radiator fin 31 in the present embodiment is sharply acute to form the acute angle C and directed toward the upstream side in the flow direction of the cooling medium. Thus, as shown by arrows in FIG. 3, the corner C of the radiator fin 31 smoothly guides the flow of the cooling medium so as to spread toward opposite sides in the lateral direction of the radiator fin 31 in the interior region S of the base 20. This further prevents the radiator fin 31 from increasing pressure loss when the cooling medium flows through the interior region S of the base 20.

According to the above embodiment, the present invention has the following advantages.

(1) The radiator fin 31 has a sidewise cross-section of which the dimension L2 in the flow direction of the cooling medium is larger than the dimension L1 in the lateral direction orthogonal to the flow direction of the cooling medium in the interior region S of the base 20. Unlike the radiator fin 31 having a circular sidewise cross-section, the dimension of the radiator fin 31 may be increased in the flow direction of the cooling medium without changing the dimension in the lateral direction orthogonal to the flow direction of the cooling medium. When the dimension of the radiator fin 31 is increased in the flow direction of the cooling medium, the heat transferred from the semiconductor element 28 is efficiently exchanged between the radiator fin 31 and the cooling medium. This improves the efficiency for cooling the semiconductor element 28. Further, the dimension of the radiator fin 31 is unchanged in the lateral direction. This prevents the radiator fin 31 from increasing flow resistance in the interior region S of the base 20. Therefore, the present embodiment suppresses an increase in pressure loss when the cooling medium passes through the interior region S of the base 20, and improves the cooling efficiency for the semiconductor element 28.

(2) The radiator fin 31 has the sidewise cross-section outlined by the four sides A1, A2, A3, and A4. The two sides A1 and A2 intersect at a section facing the upstream side in the flow direction of the cooling medium. This may further greatly decrease flow resistance by the radiator fin 31 in the interior region S of the base 20, and suppress an increase in pressure loss when the cooling medium passes through the interior region S of the base 20.

(3) In the radiator fin 31, the section at which the two sides A1 and A2 intersect is the corner C. Thus, the sidewise cross-section of the radiator fin 31 has an outline that a section facing the upstream side in the flow direction of the cooling medium sharply points to the upstream side in the flow direction of the cooling medium. This may further greatly decrease flow resistance by the radiator fin 31 in the interior region S of the base 20, and suppress an increase in pressure loss when the cooling medium passes through the interior region S of the base 20.

(4) The radiator fin 31 has a rhombic sidewise cross-section, and is relatively long in the flow direction of the cooling medium. This ensures enough rigidity of the radiator fin 31 in the flow direction of the cooling medium. The sidewise cross-section of the radiator fin 31 has the outline which is directed from the section at which the two sides A1 and A2 intersect in the flow direction of the cooling medium so as to spread toward opposite sides in the lateral direction in the interior region S of the base 20. This may decrease flow resistance by the radiator fin 31 in the interior region S of the base 20, and suppress an increase in pressure loss when the cooling medium passes through the interior region S of the base 20.

(5) A plurality of radiator fins 31 are arranged in a staggered manner, in the interior region S of the base 20. The cooling medium can smoothly flow between the radiator fins 31 arranged in the interior region S of the base 20.

This may further suppress an increase in pressure loss when the cooling medium passes through the interior region S of the base 20.

(6) The radiator fins 31 are separated from one another by the proper distance P in the lateral direction orthogonal to the flow direction of the cooling medium. This may suppress an increase in pressure loss when the cooling medium passes through the interior region S of the base 20, and improve the efficiency for cooling the semiconductor element 28.

(7) A downstream portion of a radiator fin 31a overlaps with an upstream portion of an adjacent radiator fin 31b in the direction orthogonal to the flow direction of the cooling medium. This prevents the cross-section area of a flow passage of the cooling medium formed between the radiator fins 31a and 31b from changing. This further suppresses an increase in pressure loss when the cooling medium passes through the interior region S of the base 20.

(8) The semiconductor element 28 is connected to the base 20 by the insulation substrate 27. In this connection, linear thermal expansion coefficients are different between the base 20 and the insulation substrate 27. This may greatly warp the base 20 especially in the flow direction of the cooling medium, which is a longitudinal direction of the insulation substrate 27. For example, the base 20 would be partially separated from the insulation substrate 27. In this respect, the radiator fin 31 of the present embodiment especially enhances rigidity of the base 20 in the flow direction of the cooling medium. Thus, the radiator fin 31 may preferably prevent the base 20 from such warp.

The embodiments may be modified as below.

In the embodiment, radiator fins 31 are located on the upper and lower surfaces of the support plate 32. However, only one of the surfaces, preferably the upper surface, may have radiator fins 31.

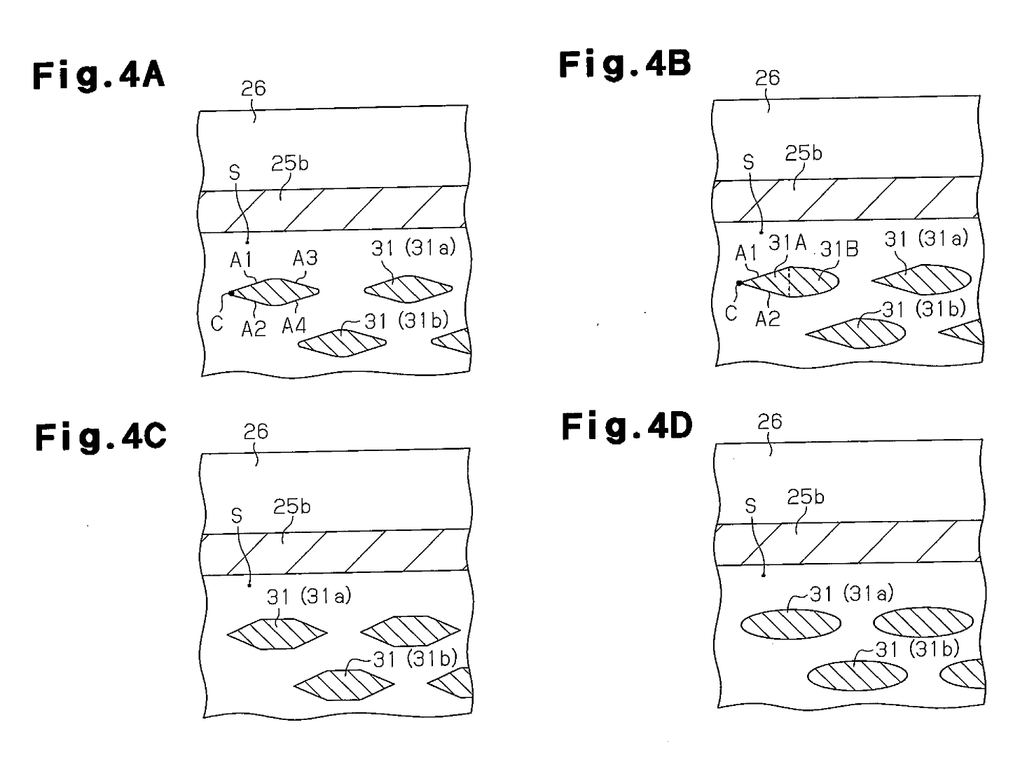

Referring to FIG. 4A, a radiator fin 31 may have a rhombic sidewise cross-section with a rounded corner C.

Referring to FIG. 4B, a radiator fin 31 may have a sidewise cross-section shaped half rhombic and half ellipsoidal. Here, a first portion 31A is a half portion of the radiator fin 31 located at the upstream side in the flow direction of the cooling medium (left side in FIG. 4B), and is half-rhombic. A second portion 31B is the other half of the radiator fin 31 located at the downstream side in the flow direction of the cooling medium (right side in FIG. 4B), and is half-ellipsoidal. That is, the radiator fin 31 may have an asymmetric sidewise cross-section in the flow direction of the cooling medium. According to such a structure, the radiator fin 31 is relatively long in the flow direction of the cooling medium. Further, the sidewise cross-section of the radiator fin 31 has an outline which is directed in the flow direction of the cooling medium so as to spread in the lateral direction of the radiator fin 31 in the base 20. This may provide the same advantages as (4) of the above embodiment.

Referring to FIG. 4C, the radiator fin 31 may have a hexagonal sidewise cross-section. Moreover, the radiator fin 31 may have a polygonal sidewise cross-section with any number of corners as far as being larger in the flow direction of the cooling medium than in the direction orthogonal to the flow direction of the cooling medium. In this case, a corner of the polygon may be either sharp or rounded.

Referring to FIG. 4D, the radiator fin 31 may have an ellipsoidal sidewise cross-section to be thin and long in the flow direction of the cooling medium. That is, the radiator fin 31 may have a sidewise cross-section smoothly outlined without intersect.

In one embodiment, the distance P may be as wide as the dimension L2. Here, the distance P is a distance between a radiator fin 31a and an adjacent radiator fin 31b in the direction orthogonal to the flow direction of the cooling medium. The dimension L2 is a length of the sidewise cross-section of the radiator fin 31 in the flow direction of the cooling medium.

In one embodiment, the radiator fin 31 may protrude with uneven widths. For example, the radiator fin 31 may have a pyramid shape or an elliptical cone shape, which tapers toward the distal end in the protrusion direction.

In one embodiment, radiator fins 31 may be arranged in a grid, as viewed from above.

In one embodiment, a number of radiator fins 31 supported on the support plate 32 may be increased or decreased.

In one embodiment, the number of radiator fins 31 supported on the upper surface of the support plate 32 and the number of radiator fins 31 supported on the lower surface of the support plate 32 may be changed.

In one embodiment, all radiator fins 31 supported on the support plate 32 are not necessarily shaped uniform. That is, the support plate 32 may support differently-shaped radiator fins 31. Some of the radiator fins 31 may have rhombic sidewise cross-sections which are relatively long in the flow direction of the cooling medium. The others may have sidewise cross-sections shaped otherwise which are relatively long in the flow direction of the cooling medium.

In one embodiment, the support plate 32 does not necessarily divide the interior region S into a top and bottom. The interior region S may receive the support plate 32 including radiator fins 31 on only one of the surfaces.

1. A cooling device comprising:
a base including an exterior, an interior, an inlet, and an outlet, wherein a heat generation element is connected to the exterior; and
a plurality of pin-shaped radiator fins located in the interior of the base at a portion near the heat generation element, wherein the radiator fins are arranged from the inlet to the outlet, wherein
the cooling device cools the heat generation element with a cooling medium flowing in the interior of the base from the inlet to the outlet,
each of the radiator fins includes a sidewise cross-section having a dimension in a flow direction of the cooling medium and a dimension in a lateral direction orthogonal to the flow direction of the cooling medium, and the dimension in the flow direction is longer than the dimension in the lateral direction, and
the radiator fins are separated from one another by a predetermined distance in the lateral direction.

2. The cooling device according to claim 1, wherein the sidewise cross-section includes an outline including two sides, the two sides are directed from an upstream side to a downstream side in the flow direction of the cooling medium and extended away from each other in the lateral direction of the corresponding radiator fin, and the two sides intersect at a section facing the upstream side in the flow direction of the cooling medium.

3. The cooling device according to claim 2, wherein the section at which the two sides intersect is a corner.

4. The cooling device according to claim 2, wherein each of the radiator fins has a rhombic sidewise cross-section.

5. The cooling device according to claim 2, wherein each of the radiator fins includes
a first portion located at an upstream side in the flow direction of the cooling medium and including the section at which the two sides intersect; and
a second portion located at a downstream side in the flow direction of the cooling medium and excluding the section at which the two sides intersect.

6. The cooling device according to claim 1, wherein each of the radiator fins has an ellipsoidal sidewise cross-section.

7. The cooling device according to claim 1, wherein the radiator fins are arranged in a staggered manner.

8. The cooling device according to claim 1, wherein the predetermined distance is shorter than or equal to the dimension in the flow direction of each of the radiator fins.

9. The cooling device according to claim 1, wherein the radiator fins include a first radiator fin and a second radiator fin arranged in the flow direction of the cooling medium, and a downstream portion of the first radiator fin overlaps with an upstream portion of the second radiator fin in the lateral direction.

10. A semiconductor device comprising:
the cooling device according to claim 1;
an insulation substrate; and
a semiconductor element serving as the heat generation element and connected to the base by the insulation substrate.
